(19) United States
(12) Patent Application Publication
(10) Pub. No.: US 2011/0151273 A1
(43) Pub. Date: Jun. 23, 2011

(54) LAMINATE FOR PRINTED CIRCUIT BOARD

(75) Inventor: Chien-Nan WU, Taipei City (TW)

(73) Assignee: SUBTRON TECHNOLOGY CO., LTD., Hsin-Chu (TW)

(21) Appl. No.: 12/760,685

(22) Filed: Apr. 15, 2010

(30) Foreign Application Priority Data
Dec. 17, 2009 (TW) 99202468

(51) Int. Cl. H05K 1/02; B32B 15/01; B32B 15/20; B32B 7/02; B32B 15/00

(52) U.S. Cl. 428/621; 428/213; 428/675; 428/647

(57) ABSTRACT

A laminate for use in the production of a printed circuit board includes a main layer and a face layer made of a material different from the material that the main layer is made of. The main layer is made of a good electrically conductive metal and has a top surface. The face layer is disposed on the top surface of the main layer and made of a material having an etching rate substantially smaller than that of the material that the main layer is made of. The laminate can exhibit a high etching factor even if the laminate is etched by a conventional etchant.

### BACKGROUND OF THE INVENTION

1. Field of the Invention

The present invention relates generally to a printed circuit board (hereinafter referred to as “PCB”), and more specifically to a laminate for use in the production of a PCB.

2. Description of the Related Art

It is well known in the manufacturing field of the semiconductor integrated circuit that the circuit pattern of a printed circuit board or a substrate for a chip package is formed by etching. In the known conventional etching methods, the wet etching, which is developed and adopted by manufacturers long time ago, is nowadays still being used extensively because of its economic advantage. Basically, the production of PCBs using a wet etching process includes the steps of disposing a conductive layer on a substrate, coating, exposing and developing a photoresist having a desired circuit pattern on the conductive layer, and removing the areas of the conductive layer that are not protected by the patterned photoresist by a strong acid or alkali liquid etchant so as to form the desired circuit traces.

Because of the isotropic etching characteristic of the liquid etchant used in the wet etching process, the etchant will not only attack the target in a vertical direction but also in a transverse direction, resulting in the so-called undercut phenomenon. Specifically speaking, if the conductive layer is a copper layer and the etchant is FeCl₃ for example, the etchant will also attack the sidewalls of the copper conductive layer that are not protected by the photoresist in addition to the desired vertical etching, causing a mushroom defect. In practice, the etching quality can be identified by the so-called etching factor.

FIG. 1 is a schematic drawing illustrating the etching factor. The so-called etching factor is defined as an inverse of a value F, i.e. etching factor is equal to 1/F. While the value F is equal to the equation of (D1−D2)/2H, i.e. F=(D1−D2)/2H; wherein D1 represents the width of the top of the circuit line, D2 represents the width of the bottom of the circuit line and H represents the height of circuit line, i.e. the thickness of the conductive layer. When the etching factor is small, the top of the circuit line is narrow and the bottom is broad. This means that the undercut phenomenon is severe and the gap between two adjacent circuit lines is reduced, such that an electron migration is likely to occur. In addition, the fine pitch circuit layout can not be realized due to the sectional area of the circuit line is not in a rectangular shape completely.

To resolve the above-mentioned problems, a solution of forming a granular copper electrodeposit between a copper foil and an insulative substrate is disclosed by Saida et al. in U.S. Pat. No. 5,545,466. According to this patent, the etching factor is enhanced up to about 8.4 to 9. Another approach disclosed in Taiwan Invention Patent Application Laid-open No. 200643224 is to use an etchant having a high etching rate. However, the specific etchant can be suitably employed for a specific copper or copper alloy only.

### SUMMARY OF THE INVENTION

It is an objective of the present invention to provide a laminate for a PCB, which has a simple construction exhibiting a high etching factor.

Another objective of the present invention is to provide a laminate for a PCB, which exhibits a high etching factor even through the laminate is etched by a conventional etchant.

Still another objective of the present invention is to provide a laminate for a PCB, which exhibits a high etching rate.

To attain the above-mentioned objectives, the laminate for a PCB provided by the present invention comprises a main layer and a face layer made of a material different from that of the main layer. The main layer is made of a good electrically conductive metal and has a top surface and a bottom surface. The face layer is made of a material having an etching rate substantially smaller than that of the material that the main layer is made of, and the face layer is disposed on the top surface of the main layer. It will be appreciated that the term “etching rate” indicated in the present invention means the thickness of the material that can be etched off by an etchant per unit time.

Another feature of the laminate provided by the present invention lies in that the thickness of the face layer is smaller than the thickness of the main layer. Preferably, the face layer may have a thickness of about 0.4 to 1.2 μm under a condition of that the main layer has a thickness of about 8 μm.

Still another feature of the laminate of the present invention lies in that the face layer may be made of nickel (Ni) or tin (Sn) under the condition of that the main layer is made of copper (Cu).

The present invention also provides a blank PCB containing an insulative substrate and the above-mentioned laminate bonded on the substrate.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing illustrating the etching factor for a circuit line;

FIG. 2 is a schematic sectional view of a laminate according to a preferred embodiment of the present invention;

FIG. 3 is a schematic drawing showing that the laminate of the present invention, which is bonded on an insulative substrate, is undergoing a wet etching process;

FIG. 4 is an electron microscope photo showing a sectional view of a circuit line formed by etching a conventional conductive layer of copper foil, and

FIG. 5 is an electron microscope photo showing a sectional view of a circuit line formed by etching the laminate of the present invention.

### DETAILED DESCRIPTION OF THE INVENTION

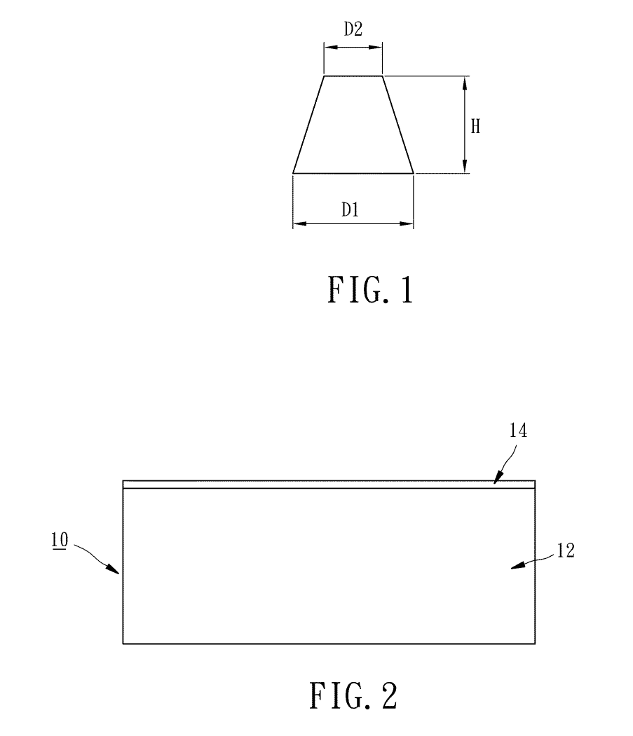

According to a preferred embodiment of the present invention, a laminate, denoted with reference numeral 10, for being used in production of a PCB comprises a main layer 12 and a face layer 14 bonded on the main layer 12, as shown in FIG. 1.

The main layer 12 may be a copper layer or a copper alloy layer, having, but not limited to, a thickness of 7.97 μm in this preferred embodiment. The face layer 14 may be a nickel layer, having, but not limited to, a thickness of 0.792 μm. The face layer 14 is removable from the main layer after the etching process.

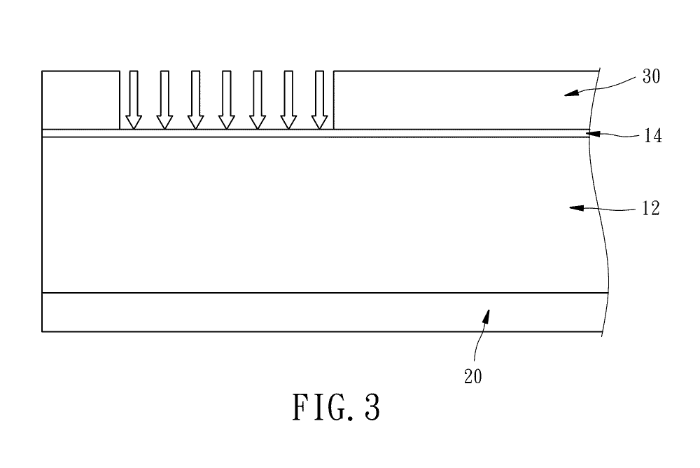

In the production of a PCB, the main layer 12 is disposed on an insulative substrate 20 and the face layer 14 is then disposed on the main layer 12 so as to form a blank PCB, as shown in FIG. 3. For disposing the main layer 12 and/or the face layer 14, coating, adhesive or electroplating method can be used. Thereafter, the blank PCB is undergone with the processes of etching treatment, such as coating photoresist 30, developing the circuit pattern and forming an etching mask, etching, and removing the etching mask and the face layer 14. It will be appreciated that the laminate 10 can of course be prepared in advance and thereafter bonded on the insulative substrate 20 for further etching treatment.

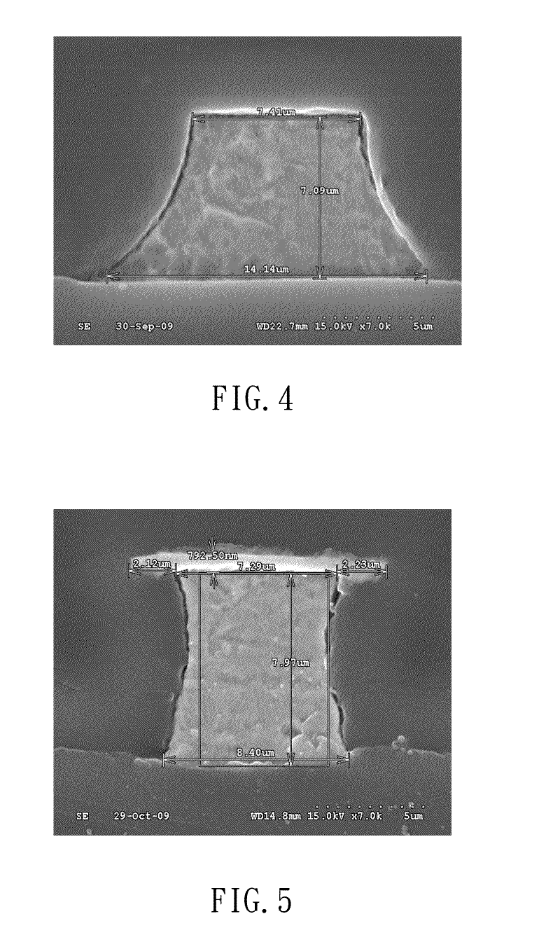

Since the laminate 10 includes a copper main layer 12 and a nickel face layer 14 that has an etching rate smaller than that of the copper main layer 12 when the laminate 10 is etched by a conventional FeCl₃ etchant, as the arrows shown in FIG. 3, the undercut phenomenon will be minimized because the sidewalls of etched zone of the copper main layer 12 will be protected by the face layer 14. As a result, the etchant can efficiently attack the laminate 10 vertically, resulting in that the etching time can be reduced and on the other hand, the difference between the width D2 of top of the circuit line and the width D1 of the bottom of the circuit line can be also reduced, i.e. the etching factor is increased. FIG. 5 is an electron microscope photo showing a sectional view of a circuit line formed after etching the laminate 10 of the present invention and removing the face layer 14. As shown in FIG. 5, the width D1, the width D2 and the height H of the circuit line, i.e. the thickness of the main layer 12, are 8.40 μm, 7.29 μm and 7.97 μm respectively, resulting in that the etching factor is 14.4. On the other hand, the circuit line formed by etching a conventional conductive layer of copper foil has, as shown in FIG. 4, a width D1 of 14.14 μm, a width D2 of 7.41 μm and a main layer thickness of 7.09 μm. Therefore, the etching factor, which is calculated from the aforesaid parameters, will be 2.2.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A laminate for a printed circuit board, the laminate comprising:
a main layer made of an electrically conductive metal and provided with an top surface, and
a face layer made of a material, which is different from the material that the main layer is made of, and disposed on the top surface of the main layer; the face layer having a thickness smaller than that of the main layer, and an etching rate smaller than that of the main layer.

2. The laminate for a printed circuit board as claimed in claim 1, wherein the main layer comprises copper or a copper alloy.

3. The laminate for a printed circuit board as claimed in claim 2, wherein the face layer comprises nickel.

4. The laminate for a printed circuit board as claimed in claim 2, wherein the face layer comprises tin.

5. The laminate for a printed circuit board, wherein the face layer is coated on the main layer in the process of forming circuit lines.

6. A blank printed circuit board comprising:
an insulative substrate;
a face layer, and
a main layer sandwiched between the insulative substrate and the face layer;
wherein the main layer is made of an electrically conductive metal;
wherein the face layer is made of a material having an etching rate smaller than that of the material that the main layer is made of;
wherein the face layer has a thickness smaller than that of the main layer.

7. The blank printed circuit board as claim in claim 6, wherein the main layer comprises copper or a copper alloy.

8. The blank printed circuit board as claimed in claim 7, wherein the face layer comprises nickel.

9. The blank printed circuit board as claimed in claim 7, wherein the face layer comprises tin.
